(19) United States
(12) Patent Application Publication
(10) Pub. No.: US 2026/0227242 A1
(43) Pub. Date: Aug. 6, 2026

(54) Ising Tag with Microacoustic Resonator for Temperature Threshold Sensor

(71) Applicant: Northeastern University, Boston, MA (US)

(72) Inventors: Cristian CASSELLA, Boston, MA (US); Nicolas CASILLI, Kendall Park, NJ (US); Hussein HUSSEIN, Boston, MA (US); Luca COLOMBO, Boston, MA (US)

(21) Appl. No.: 19/143,675

(22) PCT Filed: Mar. 11, 2024
(86) PCT No.: PCT/US2024/019458

§ 371 Date: Jun. 26, 2025

Related U.S. Application Data
(60) Provisional application No. 63/451,543, filed on Mar. 10, 2023.

(51) Int. Cl. G01K 1/024; G01K 7/32; G06K 19/067

(52) U.S. Cl. CPC G01K 1/024; G01K 7/32; G06K 19/0672

(57) ABSTRACT

Provided herein are Ising tags for threshold sensing of a parameter of interest having a first parametric oscillator (PO), a second PO coupled to and power-combined with the first PO, and a sensor element for sensing a parameter of interest, the sensor element coupling the first and second POs.

### CROSS REFERENCE TO RELATED APPLICATIONS

This application claims benefit under 35 U.S.C. § 119(e) of U.S. Provisional Application No. 63/451,543, filed on 10 Mar. 2023, entitled “Ising Tag with Microacoustic Resonator for Temperature Threshold Sensor,” the entirety of which is incorporated by reference herein.

### STATEMENT REGARDING FEDERALLY SPONSORED RESEARCH OR DEVELOPMENT

This invention was made with government support under Grant Number 2103351 awarded by the National Science Foundation. The government has certain rights in the invention.

### BACKGROUND

The emergence of the Internet of Things (IoT) in recent years has led to an unprecedented increase in the demand for wireless sensor nodes (WSNs) that effectively capture and transmit real-time parameters-of-interest (PoIs), including temperature, acidity, structural integrity, and humidity. The timely reception of information pertinent to the state of a system can be used to heighten decision making capabilities in response to critical changes in the values of PoIs. For instance, real-time temperature threshold monitoring of food transported along the cold chain would permit to flag violations in food storage conditions and enable corrective action, thereby reducing food waste and decreasing the likelihood of exposing consumers to spoiled foods. Similarly, the information accessed by real-time structural health threshold monitoring would allow for the implementation of preventative structural restoration countermeasures and issue timely evacuation warnings, saving lives and helping to preserve culturally significant buildings. Nonetheless, many of the existing WSNs embedding smart capabilities, like threshold sensing, rely on sets of battery-powered integrated circuits (ICs), which limit their versatility for widespread deployment due to either periodic battery replacement or bulky energy-harvesting architectures. Consequently, there has been an increased emphasis on developing long-lasting miniature passive tags (PTs) that demonstrate smart functionalities without exploiting batteries or ICs.

Due to the on-going Radiofrequency-Identification (RFID) revolution, deepened attention has been given to sensing techniques leveraging radiofrequency (RF) PTs. In fact, since their inception, the adoption of RF PTs as a method of sensing has been of particular interest due to their low operating power and small form factor. Many passive RF sensor tags map a PoI to their electromagnetic profile, leading to changes in RF performance that encode and backscatter the interrogation signal with respect to the sensed PoI (see FIG. 1A). However, to implement threshold sensing functionalities, many RF PTs undergo irreversible physical changes to their structures. Such changes engineer a corresponding permanent modification in their backscattering footprint above the sensed parameter's threshold. RF PTs utilizing this threshold sensing methodology, while enabling the passive memorization of violations in the PoIs, often suffer from single-use lifespans. The RF PTs that can indeed repeatably and passively memorize PoI violations face limited reprogrammability and must undergo a complete redesign or reprocessing to detect PoI violations at a different threshold. This constraints renders such RF PTs as impractical for applications, like cold-chain sensing, requiring the simultaneous monitoring of various thresholds. Additionally, such reversible threshold sensing methods are not easily implementable across different types of PoIs. Because these RF PTs rely on backscattered signals to flag PoI violations, their sensed information is left prone to inevitable distortion through multipath interference, electromagnetic cluttering, and reader's self-interference, leading to potentially severe sensing errors.

To this end, a new type of RF PT has emerged, namely Subharmonic Tags (SubHTs), contributing new avenues to passively embed both continuous and threshold sensing functionalities in a reprogrammable fashion while retaining a low operational power and small form-factor. SubHTs are nonlinear tags comprised of parametric frequency dividers (PFDs), a type of electrical parametric oscillator (PO), terminated at both input and output ports by 50Ω matched antennas. In addition to sensing, PFDs have recently gained significant attention for various applications, including frequency generation, signal processing, and even computation. The POs in SubHTs leverage the nonlinear dynamics of their varactor-based parametric circuits to passively generate an output frequency (fₒᵤₜ) that is one half of its interrogation frequency (fᵢₙ) by entering a period-doubling regime through a subcritical bifurcation phenomenon activated above a certain power threshold (Pₜₕ) (see FIG. 1B). SubHTs exhibit inherently larger read-ranges due to a 16 dB differences in path loss at their respective fₒᵤₜ values when considering the same fᵢₙ. While prior demonstrations of SubHT-based sensors have shown reconfigurable passive sensing in both continuous and threshold sensing operations, their accuracy has been inevitably hampered by sensitivity to multi-path and channel fading. This limitation is due to the triggering of SubHTs' sensing functionalities via bifurcations occurring near points of marginal stability within their nonlinear circuits.

A list of acronyms and variables referenced in this disclosure and the irrespective definitions is provided below:

| Acronym | Definition |
|---|---|
| IoT | Internet of things |
| WSN | Wireless sensor nodes |
| PoI | Parameter of Interest |
| IC | Integrated Circuit |
| PT | Passive Tag |
| RFID | Radiofrequency Identification |
| HT | Harmonic Tag |
| SubHT | SubHarmonic Tag |
| PFD | Parametric Frequency Divider |
| PO | Parametric Oscillator |
| fᵢₙ, fₒᵤₜ | Frequencies of the signal and pump modes, i.e., fᵢₙ and fₒᵤₜ are the |
| | resonant frequencies of LC tanks in the input and output meshes |
| Pₜₕ | Pump power required to excite the subharmonic generation in PFDs |
| Ising tag | Ising Tag |
| LiNbO₃ | Lithium Niobate |
| vₒᵤₜ | Output signal of the Ising tag given in voltage |
| Pₒᵤₜ | Output signal of the Ising tag given in dBm |
| Pᵢₙ | Power inputted to or incident upon the Ising tag |
| fᵣₑₛ | Resonant frequency of the LiNbO₃ resonator |
| Tₐ | Temperature applied to the LiNbO₃ resonator |
| Tₜₕ | Threshold temperature triggering a change in the dominant |
| R_{L} | Load resistance terminating the output of PFDs |
| Z_{C} | Coupling element used to couple the PFDs in Ising tags |
| P_{th, E}, P_{th, O} | Pump power required to excite the subharmonic generation in the even |
| | mode and odd mode decomposition of the Ising tag, respectively |
| BVD | Butterworth Van-Dyke Model used to map out the electrical domain |
| | characteristics of a microacoustic resonator |
| TCF | Temperature coefficient of frequency |
| Qₛₗₒₚₑ | Quality factor with respect to fᵣₑₛ |
| kₜ² | Electromechanical coupling of the LiNbO₃ resonator |
| Δφ | Phase difference between the output signals of the two coupled PFDs |
| Z₁, Z₂, Z₃ | Circuital branches comprising PFDs |
| pAG | Power auxiliary generator |
| EM | Electromagnetic |
| PCB | Printed circuit board |
| Z_{2, E}, Z_{2, O} | The Z₂ circuit branch of the PFDs in Ising tags when considering the |
| | even and odd mode decompositions, respectively |
| LVR | Laterally Vibrating Resonator |
| Rₘ | Motional resistance of the resonator when fitted to the BVD model |
| Lₘ | Motional inductance of the resonator when fitted to the BVD model |
| Cₘ | Motional capacitance of the resonator when fitted to the BVD model |
| C₀ | Static capacitance of the interdigitated structure of LVRs |
| CW | Continuous wave |
| EIRP | Effective isotropic radiated power |

### SUMMARY

Described herein are Ising tags having coupled nonlinear parametric oscillators (POs) for threshold sensing of parameters of interest (POIs). In some embodiments, such Ising tags can function as radio frequency (RF) passive tags (PTs) providing passive, robust, and reprogrammable threshold sensing insensitive to multi-path and reader self-interference.

In one aspect, an Ising tag for threshold sensing of a parameter of interest is provided. The Ising tag includes a first parametric oscillator (PO). The Ising tag also includes a second PO coupled to and power-combined with the first PO. The Ising tag also includes a sensor element for sensing a parameter of interest, the sensor element coupling the first and second POs.

In some embodiments, each PO includes a resonant input mesh driven by a pump signal. In some embodiments, each PO includes a resonant output mesh coupled to the input mesh through a nonlinear component to form a parametric frequency divider. In some embodiments, each PO includes the nonlinear component configured to passively activate, responsive to the pump signal exceeding a threshold power of the PO, a parametric oscillation between the input and output meshes having an oscillation frequency equal to half an angular input frequency of the pump signal. In some embodiments, each PO includes wherein an output signal of PO can be switched between an in-phase state and an out-of-phase state. In some embodiments, the sensor element is configured to set the threshold power of the first and second POs to be exceeded by a power of the pump signal responsive to a value of the parameter of interest exceeding a parameter of interest threshold. In some embodiments, the sensor element includes one or more resistive elements, inductive elements, capacitive elements, resonant elements, or combinations thereof. In some embodiments, the sensor element produces a capacitive readout. In some embodiments, the sensor element includes capacitive elements only. In some embodiments, the sensor element is one or more of an environmental sensor, a chemical sensor, a biological sensor, a biomedical sensor, an electrical sensor, mechanical sensor, or combinations thereof. In some embodiments, the sensor element is a temperature sensor. In some embodiments, the sensor element is a piezoelectric resonator. In some embodiments, the sensor element is a lithium niobate (LiNbO₃) resonator.

In some embodiments, a characteristic of the nonlinear component is modulated at the angular input frequency of the pump signal. In some embodiments, the nonlinear component has a nonlinear reactance. In some embodiments, the nonlinear component includes one or more of a diode, a varactor, or a combination thereof. In some embodiments, the nonlinear component includes a varactor and an inductor, wherein the input mesh and the output mesh are coupled through the varactor and the inductor. In some embodiments, the input mesh includes an input filter to constrain the pump signal within the input mesh to the angular input frequency of the pump signal. In some embodiments, the output mesh includes an output filter to constrain the output signal within the output mesh to half of the angular input frequency of the pump signal. In some embodiments, the output mesh is configured to series-resonate at half the angular input frequency of the pump signal. In some embodiments, each of the input mesh and the output mesh includes a resonator. In some embodiments, each resonator includes one or more of an electrical resonator, a MEMS resonator, a NEMS resonator, an optical resonator, a non-Hermitian resonator, an electromagnetic resonator, or a combination thereof.

In another aspect, a multiple parameter of interest threshold sensing system is provided. The multiple parameter of interest threshold sensing system includes a first Ising tag. The first Ising tag includes a first parametric oscillator (PO). The first Ising tag also includes a second PO coupled to and power-combined with the first PO. The first Ising tag also includes a first sensor element for sensing a first parameter of interest, the first sensor element coupling the first and second POs. The multiple parameter of interest threshold sensing system also includes a second Ising tag. The second Ising tag also includes a third parametric oscillator (PO). The second Ising tag also includes a fourth PO coupled to and power-combined with the first PO. The second Ising tag also includes a second sensor element for sensing a second parameter of interest, the second sensor element coupling the third and fourth POs. The multiple parameter of interest threshold sensing system also includes wherein the first sensor element is configured to set a threshold power of the first and second POs to be exceeded by a power of a pump signal responsive to a value of the first parameter of interest exceeding a first parameter of interest threshold. The multiple parameter of interest threshold sensing system also includes wherein the second sensor element is configured to set a threshold power of the third and fourth POs to 5 be exceeded by a power of the pump signal responsive to a value of the second parameter of interest exceeding a second parameter of interest threshold.

In some embodiments, the first and second sensor elements each include one or more of an environmental sensor, a chemical sensor, a biological sensor, a biomedical sensor, an electrical sensor, mechanical sensor, or combinations thereof.

In a further aspect, a system for threshold sensing of a parameter of interest is provided. The system for threshold sensing of a parameter of interest includes an Ising tag. The Ising tag includes a first parametric oscillator (PO). The Ising tag also includes a second PO coupled to and power-combined with the first PO. The Ising tag also includes a sensor element for sensing a parameter of interest, the sensor element coupling the first and second POs. Each PO includes a resonant input mesh driven by a pump signal. Each PO also includes a resonant output mesh coupled to the input mesh through a nonlinear component to form a parametric frequency divider. Each PO also includes the nonlinear component configured to passively activate, responsive to the pump signal exceeding a threshold power of the PO, a parametric oscillation between the input and output meshes having an oscillation frequency equal to half an angular input frequency of the pump signal. Each PO also includes wherein an output signal of the PO can be switched between an in-phase state and an out-of-phase state. The Ising tag also includes wherein the sensor element is configured to set the threshold power of the first and second POs to be exceeded by a power of the pump signal responsive to a value of the parameter of interest exceeding a parameter of interest threshold. The Ising tag also includes wherein an output signal of the Ising tag can be switched between an in-phase state and an out-of-phase state according to a combined state of the output signals of the first and second POs. The system for threshold sensing of a parameter of interest also includes a reader configured to produce the pump signal and to read the output signal, wherein the reader is configured to detect the in-phase or out-of-phase state of the Ising tag.

Additional features and aspects of the technology include the following:
1. An Ising tag for threshold sensing of a parameter of interest comprising:
   a first parametric oscillator (PO);
   a second PO coupled to and power-combined with the first PO; and
   a sensor element for sensing a parameter of interest, the sensor element coupling the first and second POs.
2. The Ising tag of feature 1, wherein each PO comprises:
   a resonant input mesh driven by a pump signal;
   a resonant output mesh coupled to the input mesh through a nonlinear component to form a parametric frequency divider; and
   the nonlinear component configured to passively activate, responsive to the pump signal exceeding a threshold power of the PO, a parametric oscillation between the input and output meshes having an oscillation frequency equal to half an angular input frequency of the pump signal,
   wherein an output signal of PO can be switched between an in-phase state and an out-of-phase state.
3. The Ising tag of feature 2, wherein the sensor element is configured to set the threshold power of the first and second POs to be exceeded by a power of the pump signal responsive to a value of the parameter of interest exceeding a parameter of interest threshold.
4. The Ising tag of any of features 1-3, wherein the sensor element includes one or more resistive elements, inductive elements, capacitive elements, resonant elements, or combinations thereof.
5. The Ising tag of feature 4, wherein the sensor element produces a capacitive readout.
6. The Ising tag of any of features 4-5, wherein the sensor element includes capacitive elements only.
7. The Ising tag of any of features 4-6, wherein the sensor element is one or more of an environmental sensor, a chemical sensor, a biological sensor, a biomedical sensor, an electrical sensor, a mechanical sensor, or combinations thereof.
8. The Ising tag of feature 7, wherein the sensor element is a temperature sensor.
9. The Ising tag of feature 8, wherein the sensor element is a piezoelectric resonator.
3. The Ising tag of feature 9, wherein the sensor element is a lithium niobate (LiNbO₃) resonator.
11. The Ising tag of any of features 2-10, wherein a characteristic of the nonlinear component is modulated at the angular input frequency of the pump signal.
12. The Ising tag of any of features 2-11, wherein the nonlinear component has a nonlinear reactance.
13. The Ising tag of feature 12, wherein the nonlinear component includes one or more of a diode, a varactor, or a combination thereof.
14. The Ising tag of feature 13, wherein the nonlinear component includes a varactor and an inductor, wherein the input mesh and the output mesh are coupled through the varactor and the inductor.
15. The Ising tag of any of features 2-14, wherein:
   the input mesh includes an input filter to constrain the pump signal within the input mesh to the angular input frequency of the pump signal; and
   the output mesh includes an output filter to constrain the output signal within the output mesh to half of the angular input frequency of the pump signal.
16. The Ising tag of any of features 2-15, wherein the output mesh is configured to series-resonate at half the angular input frequency of the pump signal.
17. The Ising tag of any of features 2-16, wherein each of the input mesh and the output mesh includes a resonator.
18. The Ising tag of feature 17, wherein each resonator includes one or more of an electrical resonator, a MEMS resonator, a NEMS resonator, an optical resonator, a non-Hermitian resonator, an electromagnetic resonator, or a combination thereof.
19. A multiple parameter of interest threshold sensing system comprising:
   a first Ising tag including:
      a first parametric oscillator (PO);
      a second PO coupled to and power-combined with the first PO; and
      a first sensor element for sensing a first parameter of interest, the first sensor element coupling the first and second POs; and
   a second Ising tag including:
      a third parametric oscillator (PO);
      a fourth PO coupled to and power-combined with the first PO; and
      a second sensor element for sensing a second parameter of interest, the second sensor element coupling the third and fourth POs,
   wherein the first sensor element is configured to set a threshold power of the first and second POs to be exceeded by a power of a pump signal responsive to a value of the first parameter of interest exceeding a first parameter of interest threshold, and
   wherein the second sensor element is configured to set a threshold power of the third and fourth POs to be exceeded by a power of the pump signal responsive to a value of the second parameter of interest exceeding a second parameter of interest threshold.
20. The multiple parameter of interest threshold sensing system of feature 19, wherein the first and second sensor elements each include one or more of an environmental sensor, a chemical sensor, a biological sensor, a biomedical sensor, an electrical sensor, a mechanical sensor, or combinations thereof.
21. A system for threshold sensing of a parameter of interest comprising:
   an Ising tag including:
      a first parametric oscillator (PO);
      a second PO coupled to and power-combined with the first PO; and
      a sensor element for sensing a parameter of interest, the sensor element coupling the first and second POs;
      wherein each PO comprises:
         a resonant input mesh driven by a pump signal;
         a resonant output mesh coupled to the input mesh through a nonlinear component to form a parametric frequency divider; and
         the nonlinear component configured to passively activate, responsive to the pump signal exceeding a threshold power of the PO, a parametric oscillation between the input and output meshes having an oscillation frequency equal to half an angular input frequency of the pump signal,
         wherein an output signal of the PO can be switched between an in-phase state and an out-of-phase state,
      wherein the sensor element is configured to set the threshold power of the first and second POs to be exceeded by a power of the pump signal responsive to a value of the parameter of interest exceeding a parameter of interest threshold,
      wherein an output signal of the Ising tag can be switched between an in-phase state and an out-of-phase state according to a combined state of the output signals of the first and second POs; and
   a reader configured to produce the pump signal and to read the output signal, wherein the reader is configured to detect the in-phase or out-of-phase state of the Ising tag.

### BRIEF DESCRIPTION OF THE DRAWINGS

FIG. 1A illustrates a symbolic representation of prior art RF passive tags that enable threshold sensing through some change in their underlying electromagnetic profiles which is reflected in their linearly backscattered response signals. While some implementations may be reversible, these types of passive threshold sensors struggle with sensitivity to multi-path, power-dependent output, and limited range of PoI sensing.

FIG. 1B illustrates a symbolic representation of prior art nonlinear tags which generally implement threshold sensing through the manipulation of bifurcation dynamics near points of marginal stability. While these nonlinear tags are reversible and reconfigurable, their sensing accuracy is power-dependent as their set threshold varies with respect to incident power.

FIG. 2A illustrates a symbolic representation of Ising tags in accordance with various embodiments. Such Ising tags are a new class of nonlinear tags exploiting the synchronization dynamics of two coupled parametric oscillators (POs) to implement threshold sensing. Such an approach renders the accuracy of this tag insensitive to perturbations in received power as its synchronization dynamics and threshold setting mechanism operate independently of the Pᵢₙ. The sensing threshold of Ising tags is also remotely and electronically reconfigurable by changing the fᵢₙ, allowing the Ising tag to flag violations of various thresholds of a diverse set of potential PoIs almost simultaneously.

FIG. 2B illustrates a simplified circuit schematic of an Ising tag having two POs coupled by a coupling element and power combined at its output. The Ising tag is terminated using an input and output antenna operating at fᵢₙ and fᵢₙ/2, respectively.

FIG. 2C illustrates an example of the phase synchronization dynamics of the Ising tag of FIG. 2B by which it embeds its PoI threshold sensing functionality. As can be seen, below a certain PoIₜₕ, the Ising tag's coupled POs operate out of phase and operate in-phase above such PoIₜₕ.

FIG. 2D illustrates νₒᵤₜ of the Ising tag below the PoIₜₕ (e.g., when the POs synchronize anti-phase) and above the threshold (e.g., when the POs synchronize in-phase). This functionality permits the Ising tag to trigger a strong alarm signal when the sensed Tₐ surpasses an electronically and remotely reconfigurable Tₜₕ.

FIG. 3A illustrates a simplified circuit schematic of an Ising tag in accordance with various embodiments. As shown, the POs comprising the Ising tag are coupled together using an arbitrary coupling element Z_{C}. The Ising tag's circuit is cut along its axis of symmetry and configured such that an open circuit is placed along all cuts in the even mode while each cut is grounded in the odd mode. Thus, Even-Odd Mode symmetry analysis can be used to map the behavior of the Ising tag.

FIG. 3B illustrates an even mode decomposition subcircuit of the Ising tag of FIG. 3A when scrutinized using symmetry analysis. As shown, the R_{L} at the output of the Ising tag is unaffected by Z_{C} in the Ising tag.

FIG. 3C illustrates an odd mode decomposition subcircuit of the Ising tag of FIG. 3A, showing that the presence of Z_{C} in the Ising tag maps to some change in the parametric dynamics of the resultant system.

FIG. 3D illustrates a circuit schematic of a single PFD hosting one of the POs of the Ising tag of FIG. 3A, showing that the output backscattered signal, fₒᵤₜ, exhibits half the frequency as fᵢₙ.

FIG. 3E illustrates exemplary ranges of P_{th,E} and P_{th,O}. While P_{th,E} is unchanging as it represents the Pₜₕ of a single PFD, P_{th,O} is subject to a range of values around P_{th,E} depending on the impact of Z_{C} on the odd mode subcircuit's parametric gain efficiency and total dissipative losses.

FIG. 4A illustrates numerically extracted trends of the difference between P_{th,E} and P_{th,O} for the Ising tag of FIG. 3A when considering Z_{C} to be a purely resistive element ranging from 0Ω to 1 kΩ.

FIG. 4B illustrates numerically extracted trends of the difference between P_{th,E} and P_{th,O} for the Ising tag of FIG. 3A when considering Z_{C} to be a purely inductive element with a reactance ranging from −1 jkΩ to 1 jkΩ.

FIG. 4C illustrates numerically extracted trends of the difference between P_{th,E} and P_{th,O} for the Ising tag of FIG. 3A when considering Z_{C} to be a purely capacitive element with a reactance ranging from −1 jkΩ to 0 jΩ.

FIG. 4D illustrates an odd mode decomposition subcircuit of the Ising tag of FIG. 3A wherein the arbitrary Z_{C} coupling element is replaced, as in the prototype Ising tag of FIG. 5A, with a BVD model of a LiNbO₃ microacoustic resonator with temperature-dependent fᵣₑₛ.

FIG. 4E illustrates numerically extracted trends of the difference between P_{th,E} and P_{th,O} for the Ising tag of FIG. 3A for different Tₐ when considering Z_{C} as the BVD model illustrated in 4D. This trend shows a temperature-dependent change in the synchronization dynamics owing to temperature sensitivities embedded within LiNbO₃.

FIG. 5A illustrates a simplified circuit schematic of prototype Ising tag, having two POs coupled using a LiNbO₃ resonator and power combined at its output. The Ising tag is terminated using an input and output antenna operating at fᵢₙ and fᵢₙ/2, respectively, and is used specifically for temperature threshold sensing.

FIG. 5B illustrates measured Pₜₕ extracted for each PFD in the prototype Ising tag of FIG. 5A and then averaged together across a range of fᵢₙ.

FIG. 5C illustrates measured Pₒᵤₜ of the prototype Ising tag of FIG. 5A when wirelessly interrogated over a range of fᵢₙ and considering different Tₐ.

FIG. 5D illustrates measured trends of Δφ with respect to increasing values of Pᵢₙ at fₒᵤₜ=432.3 MHz and fₒᵤₜ=431.3 MHz when Tₐ=50° C. for the prototype Ising tag of FIG. 5A.

FIG. 5E illustrates measured Pow extracted in a wired experiment in which the prototype Ising tag of FIG. 5A is activated using several different fixed fₒᵤₜ for increasing Tₐ and Pᵢₙ.

FIG. 5F illustrates measured and numerically predicted trends of the parametric reconfigurability of Tₜₕ with respect to fₒᵤₜ for cold-chain applications for the prototype Ising tag of FIG. 5A.

FIG. 5G illustrates measured and numerically predicted trends of the parametric reconfigurability of Tₜₕ with respect to fₒᵤₜ for hot-chain applications for the prototype Ising tag of FIG. 5A.

FIG. 5H illustrates experimental results showing the transition between PO interactions from anti-ferromagnetic to ferromagnetic once Tth=40° C. has been exceeded. Below Tₜₕ, the magnitude of _{νout} is negligible due to the anti-ferromagnetic interaction between POs. Above Tₜₕ, when the interaction is ferromagnetic, _{νout} is much stronger and can act as an alarm signal, independently of received power.

FIG. 6A illustrates a circuit schematic of a PFD delineating which components correspond to the Z₁, Z₂, and Z₃ branches thereof.

FIG. 6B illustrates a simplified symbolic schematic of a PFD showing only the Z₁, Z₂, and Z₃ branches.

FIG. 6C illustrates the 4 resonance conditions which govern the generation of the subharmonic oscillation of the PFTD of FIG. 6B and minimize Pₜₕ.

FIG. 6D illustrates a circuit schematic of Z_{2,E}, which is the even mode decomposition of the Z₂ branch of an Ising tag. Note that Z_{2,E} is identical to the Z₂ of a single PFD (shown in FIG. 6A).

FIG. 6E illustrates a circuit schematic of the odd mode decomposition of the Ising tag when both PFDs are coupled together using a LiNbO₃ resonator, represented using the BVD model. As shown, while the inclusion of the BVD components reduces the amount of dissipative loading in the system, such reactive components embedded in parallel to R_{L} may lead to a detuning of the natural frequency of the PFD and a consequently degraded P_{th,O}.

FIGS. 7A-7D illustrate a method for fabricating a LiNbO₃ microacoustic resonator in accordance with various embodiments.

FIG. 7E illustrates a SEM image of a fabricated LiNbO₃ microacoustic resonator in accordance with various embodiments.

FIG. 8A illustrates measured and fitted admittance of the fabricated LiNbO₃ resonator of FIG. 7E as extracted by directly probing the device.

FIG. 8B illustrates a zoomed in view of the measured admittance around fᵣₑₛ for various Tₐ of the fabricated LiNbO₃ resonator of FIG. 7E when wirebonded onto a PCB hosting the Ising tag.

FIG. 8C illustrates a measured trend of fᵣₑₛ with respect to Tₐ used to extract a first order approximation of the Ising tag's TCF.

FIG. 8D illustrates a schematic of a temperature dependent BVD model used in circuit simulations mapping the Ising tag's behavior.

FIG. 9 illustrates a schematic of an experimental setup used for a wired experiment characterizing Pₒᵤₜ with respect to fᵢₙ, Tₐ, and Pᵢₙ. A signal generator is connected directly to the input of the Ising tag and the output signal is connected to a spectrum analyzer where the logarithmic magnitude of Pₒᵤₜ is measured.

FIG. 10 illustrates a schematic of an experimental setup used for a wireless experiment. A signal generator connected to a power amplifier and to a directive antenna interrogates the Ising tag placed onto a heating element. The backscattered signal is captured via an antenna through a spectrum analyzer and Pour is recorded for each value of fᵢₙ and Tₐ.

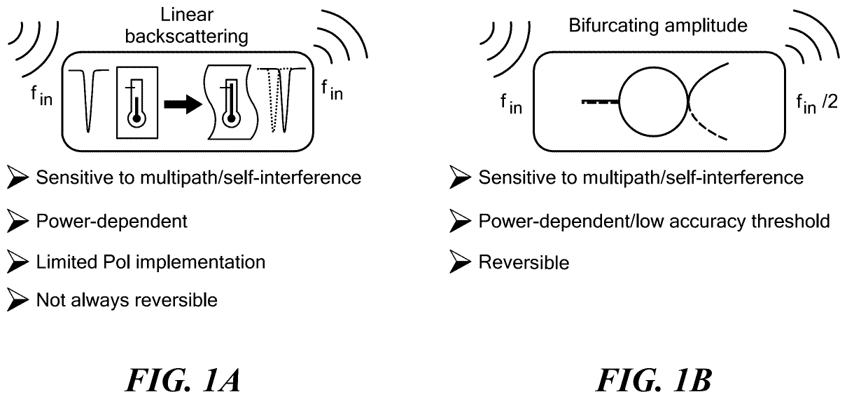

### DETAILED DESCRIPTION

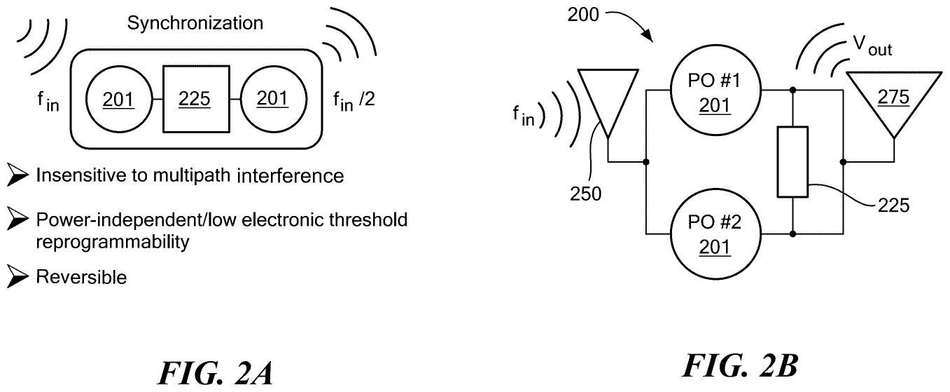

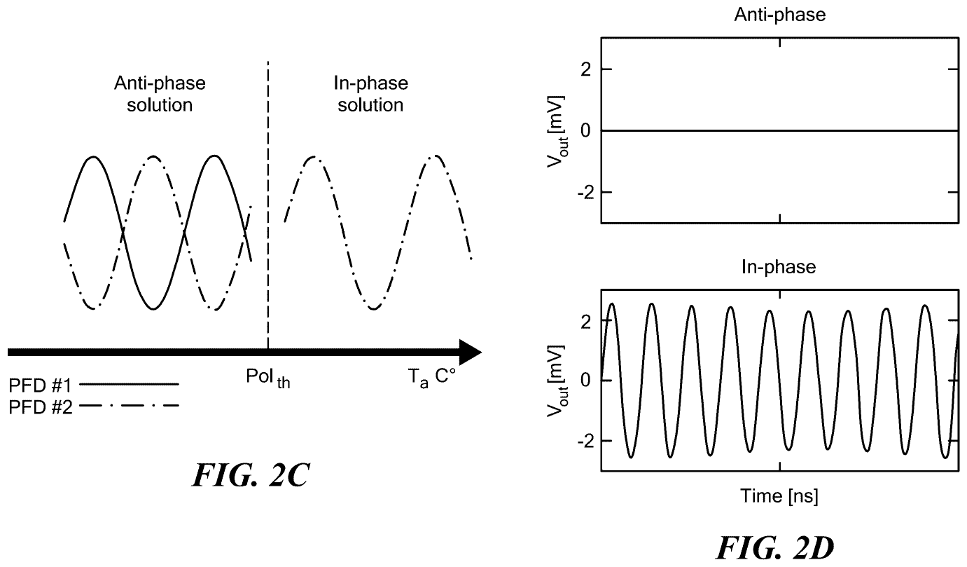

Described herein are Ising tags having coupled nonlinear parametric oscillators (POs) for threshold sensing of parameters of interest (POIs). In some embodiments, such Ising tags can function as radio frequency (RF) passive tags (PTs) providing passive, robust, and reprogrammable threshold sensing insensitive to multi-path and reader self-interference (see FIG. 2A).

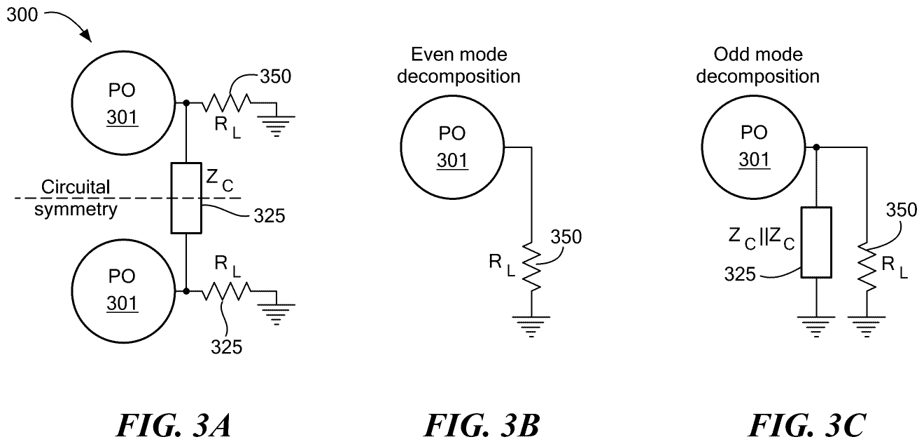

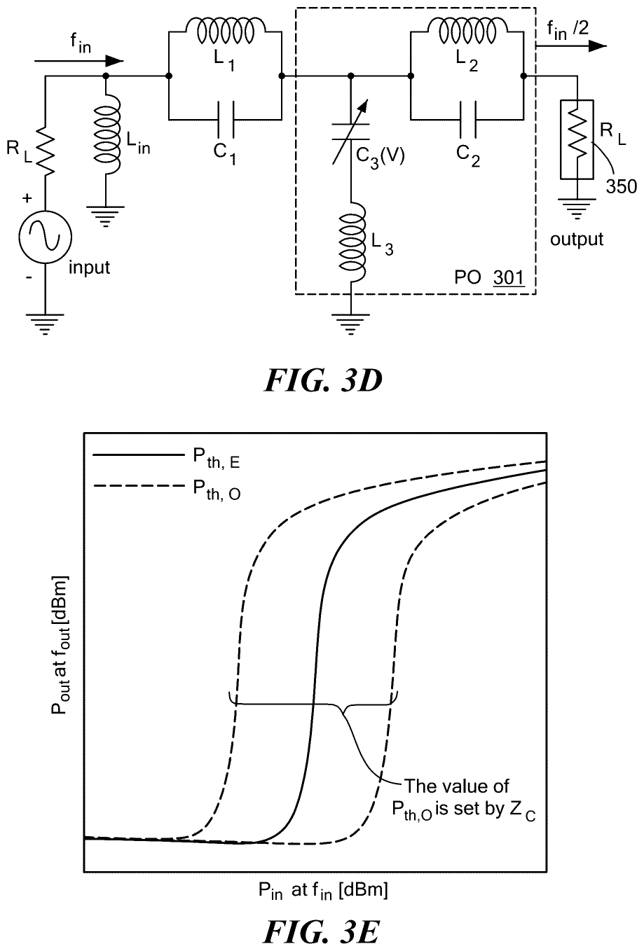

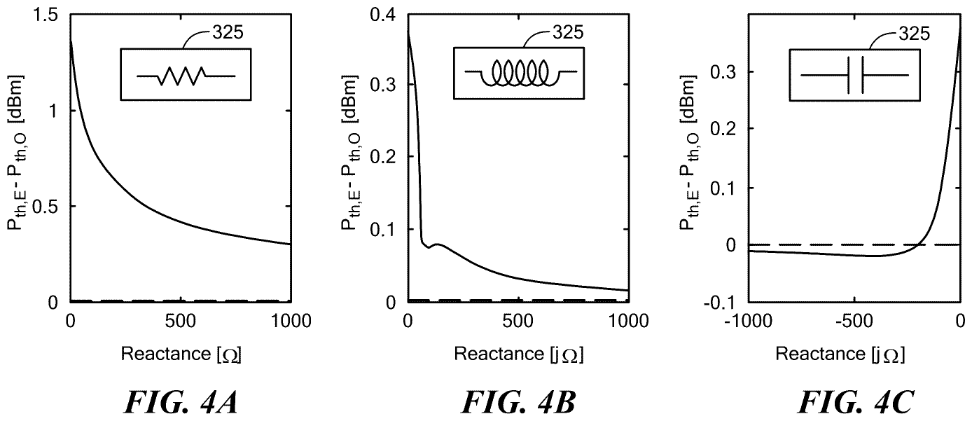

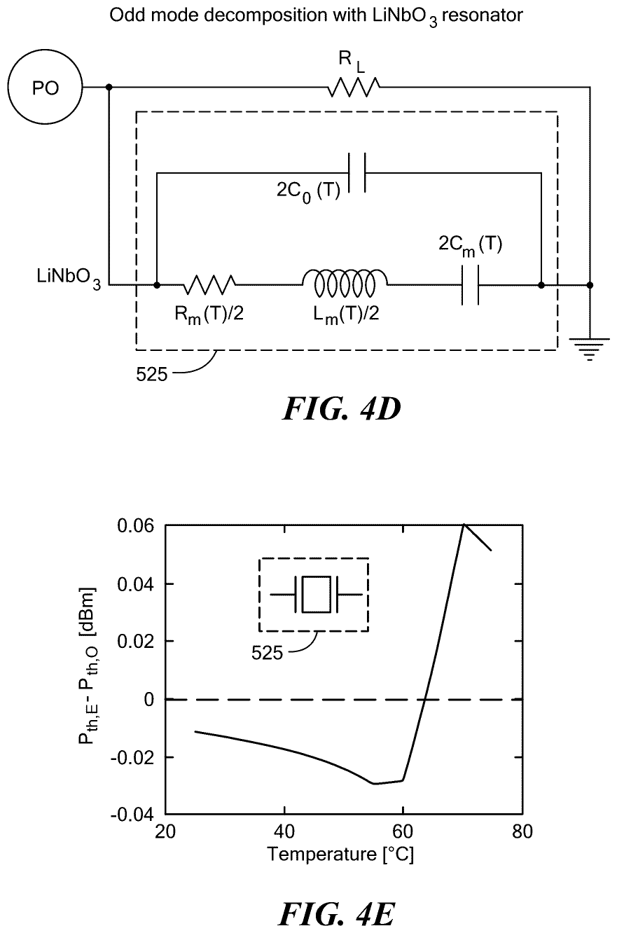

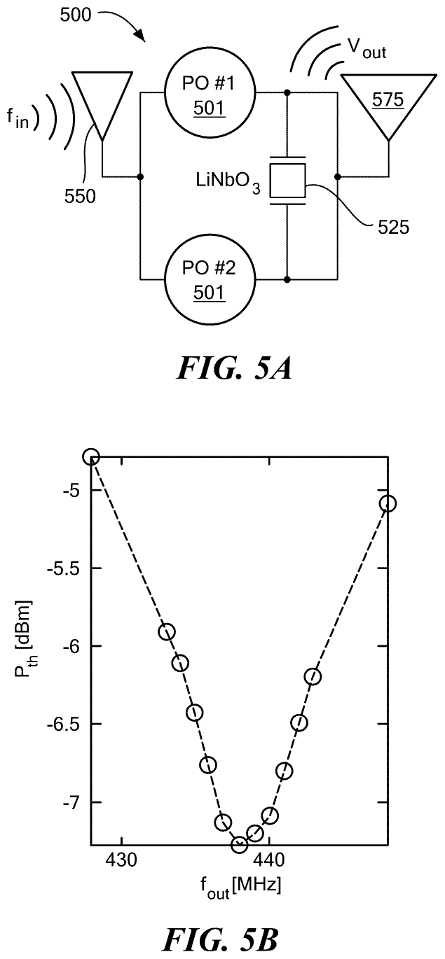

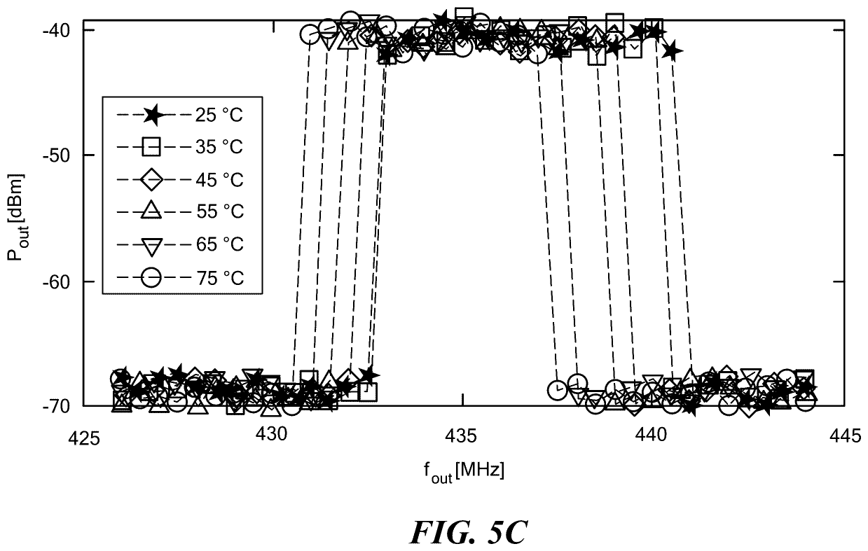

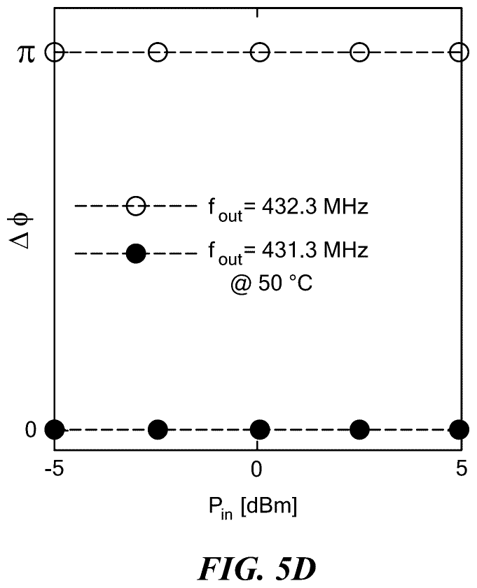

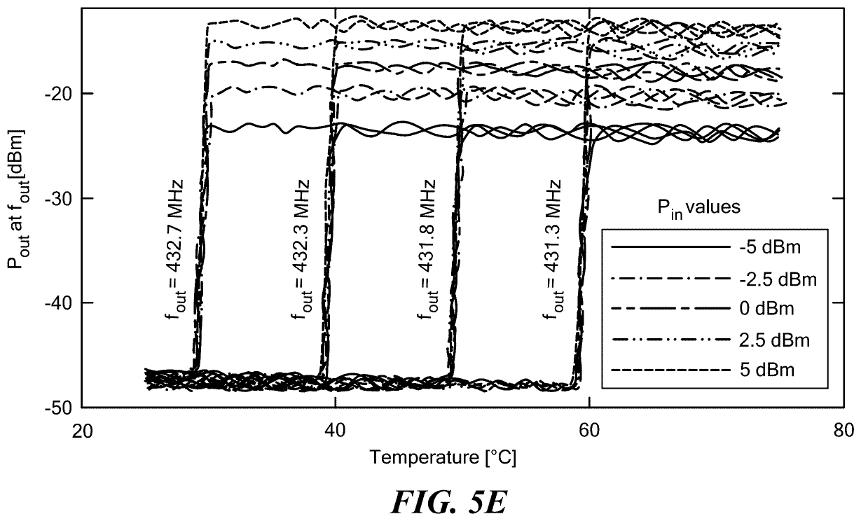

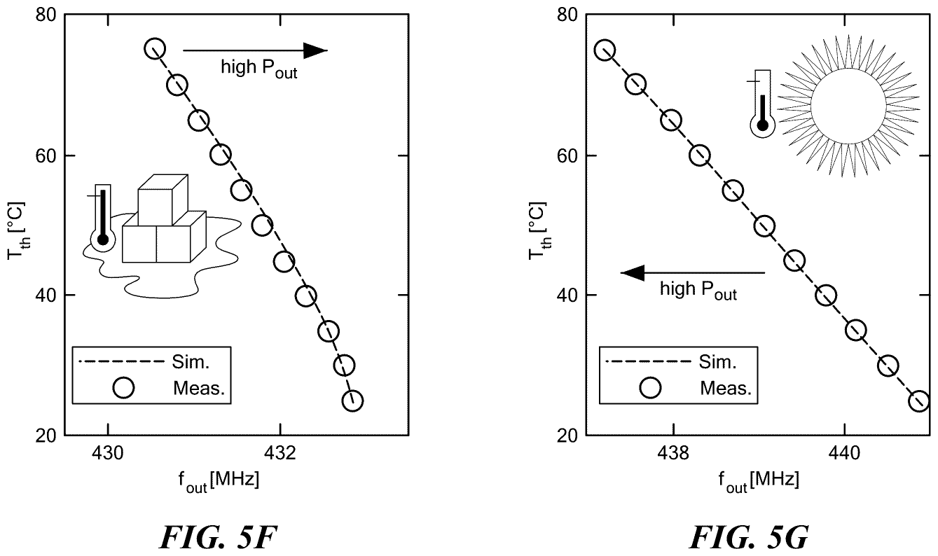

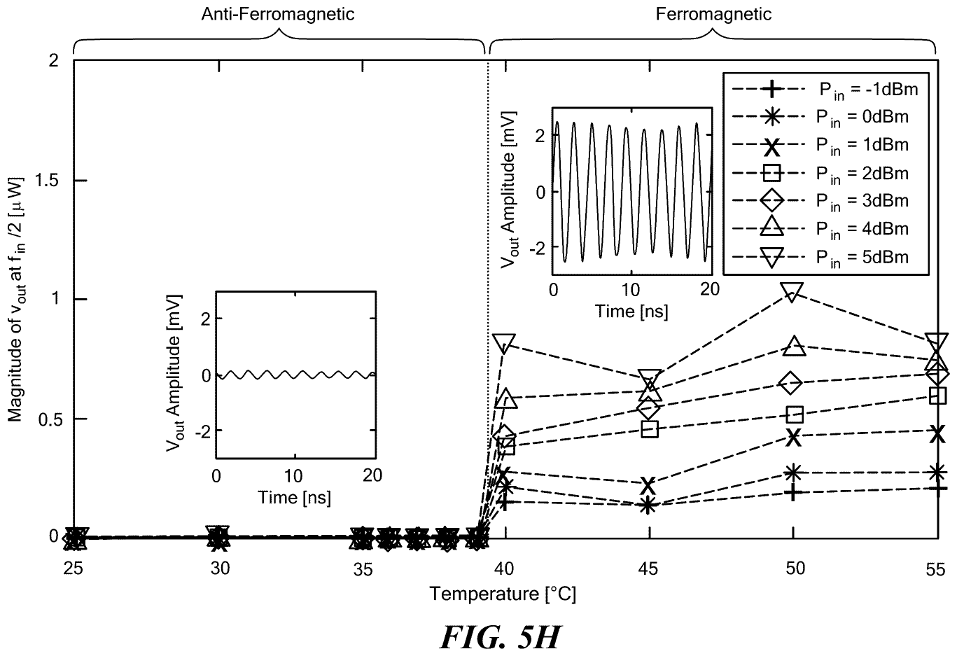

Referring now to FIGS. 2A-2D and 3A-3D. In some temperature sensing embodiments, such Ising tags 200, 300 can include two identical POs 201, 301 coupled together using a coupling element 225, 325 (see for example, various coupling elements shown in FIGS. 4A-4E and the Lithium Niobate (LiNbO₃) resonator 525 as used in connection with the experimental prototype illustrated in FIG. 5A) with power combined outputs to form the Ising tags' 200, 300 output signal, νₒᵤₜ having an output power Pour. Like SubHTs, the Ising tags' 200, 300 fₒᵤₜ is equal to one half of fᵢₙ given that the input power (Pᵢₙ) at fᵢₙ exceeds Pₜₕ. When the coupled POs 201, 301 are excited above Pₜₕ, their resultant subharmonic oscillations exhibit bistable phase states that exist at a 0 or π shift with respect to some reference output. Ising tags 200, 300 then generate a singular νₒᵤₜ by power-combining the synchronized outputs of the coupled bistable POs 201, 301. As seen in FIGS. 2C-2D, the two scenarios of phase synchronization: in-phase (even mode) and anti-phase (odd mode) yield different magnitudes of νₒᵤₜ when power combined due to additive or destructive interference, respectively. In this regard, the magnitudes of νₒᵤₜ and Pₒᵤₜ encode the Ising tags' final phase synchronization state, which is deterministically configured by the element coupling the POs 201, 301.

The coupling element 225, 325 can be any element dependent on a parameter of interest (PoI) to produce a change in the Ising tag's 200, 300 synchronization dynamics and therefore the magnitude of vₒᵤₜ. In practice, the coupling element 225, 325 can include any suitable capacitive or resonant element or combination of elements, including, for example, a capacitor, a surface acoustic wave resonator, a microacoustic resonator, a piezoelectric resonator, a cavity resonator, or any other suitable elements. Furthermore, such coupling elements 225, 325 can be or include any sensor that is sensitive to any PoI, including, for example, any environmental sensor, chemical sensor, biological sensor, biomedical sensor, electrical sensor, mechanical sensor, or combinations thereof. Such sensors can include, for example and without limitation, temperature sensors, humidity sensors, air quality sensors, soil monitoring sensors, wind sensors, rain sensors, gas sensors, pressure sensors, viscosity sensors, water quality sensors, optical sensors, light sensors, radiation sensors, infrared sensors, biosensors, planar waveguide sensors, electrochemical sensors, nanosensors, proximity sensors, pressure sensors, ultrasound sensors, accelerometers, touch/tactile sensors, photoelectric sensors, force sensors, tilt sensors, hall sensors, color sensors, flow sensors, decibel sensors, audio sensors, location sensors, position sensors, heartbeat sensors, strain gauges, magnetic sensors, vibration sensors, vacuum sensors, blood chemistry sensors, body fluid chemistry sensors, biophysical sensors, biomedical sensors, EMG sensors, ECG sensors, pulse oximetry sensors, glucose sensors, any other suitable sensor, or combinations thereof.

For example, in the embodiments shown and described in connection with the experimental, temperature threshold sensing Ising tag shown and described in FIGS. 5A-5H below, through the adoption of some temperature dependent coupling element like the LiNbO₃ resonator 525, sufficiently large changes in the temperature applied (Tₐ) to the prototype Ising tag 500 result in a change in its synchronization dynamics and therefore the magnitude of vₒᵤₜ. This mapping of the phase synchronization to Tₐ is one example of the basis for embedding threshold sensing in Ising tags 200, 300, 500 more generally, through the detection of an amplitude change in νₒᵤₜ or the backscattered Pₒᵤₜ. Moreover, the synchronization dynamics of Ising tags 200, 300 described herein also result in remotely and electronically reconfigurable sensing thresholds because the thresholds can be tuned passively through the strategic selection of fᵢₙ with respect to the resonant frequency (fᵣₑₛ) of the coupling element 225, 325. Coupled with the reversibility of the changes in fᵣₑₛ and the power-independent nature of the synchronization dynamics above threshold, Ising tags 200, 300, as a sensing architecture, open many avenues for enabling robust, long-lasting passive threshold sensing while remaining insensitive to multipath constraints. The principle of operation of the phase synchronization between the coupled POs as well as the experimental methods used to characterize the Ising tags disclosed herein are discussed below.

Referring now to FIGS. 3A-3E, Ising tags 300 disclosed herein achieve a fundamental advantage in sensing capabilities compared to the current state of the art. Compared to RFID tags relying on ICs and batteries, the Ising tag exhibits a fully passive architecture, allowing it to be used for indefinite periods of time in difficult-to-reach places without requiring any obstructive or intrusive component replacements. Even more, Ising tags 300 are advantageously capable of reconfiguring their PoI threshold remotely and parametrically through shifting the interrogating signal's frequency, marking a significant departure from the limitations of conventional RF PT technologies which often require an extensive reprocessing of the tags to change their PoI thresholds. While other RF PT threshold sensing topologies face limitations in the types of PoI violations that can be detected using their innate architecture, any PoI-sensitive coupling element with a capacitive read-out can be embedded within Ising tags to enable threshold sensing across a host of PoIs. With regard to other nonlinear tags, the Ising tag's sensing functionality uses a different set of nonlinear dynamics, relying on power-independent phase synchronization rather than bifurcation-based amplitude dynamics to encode the output signal and instantiate threshold sensing. The exploitation of the nonlinear synchronization dynamics of coupled PFDs endows the Ising tag 300 as a sensing system with robust attributes, particularly in its insensitivity to perturbations in received power above Pₜₕ, its parametric reconfigurability, and its architecture facilitating the adoption of various PoI modalities.

Accordingly, Ising tags provide significant improvements and cost reductions with respect to the use of WSNs for threshold sensing of PoIs such as, for example, temperature threshold violation monitoring in food cold chain transportation applications. To illustrate the advantages of Ising tags, even in connection with just this food cold chain transportation application, Ising tag based WSNs can be embedded within electromagnetically chaotic cold chain transportation environments, where conventional tags are unreliable, and can be used to detect when the ambient temperature localized near the Ising tag exceeds a specific value. In this context, the Ising tags would be able to flag violations of the defined Tₜₕ, signaling that certain foods or vaccines are being exposed to unsafe temperatures. When the Ising tag is interrogated frequently enough, such signaling can provide a user with sufficient time to implement corrective action by changing the storage conditions of the products, thereby reducing spoilage and waste. Even more, such an implementation would reduce the likelihood that consumers are sold spoiled or unviable products, minimizing their risk of disease due to the consumption of rotten foods.

Furthermore, such Ising tags can be reused indefinitely due to their lumped circuit architecture and can be reprogrammed to different PoI thresholds. Therefore, such tags can be continuously effective when monitoring the control of transported products and can be repurposed for different loads requiring different safe temperature specifications.

### Even and Odd Mode Competition in Coupled POs

One of the key attributes of Ising tags is their exploitation of the phase synchronization dynamics of coupled POs to trigger strong or weak output signals under certain input conditions. This is done using POs known as parametric frequency dividers (PFDs) as shown, for example, in FIG. 3D. Such PFDs can advantageously maximize the voltage modulation across their embedded nonlinear elements to passively generate subharmonic oscillations obeying bistable phase criteria because the PFDs' circuit meshes contributing to subharmonic generation can be regarded as degenerate parametric oscillators (POs) without loss of generality. When coupled together to form an Ising tag 300, the preferred phase synchronization solution (in-phase or anti-phase) of the POs is determined by the coupling element (Z_{C}) 325, which configures the energy profiles of the system's solution states.

For example, in the case of the prototype Ising tag 500 of FIG. 5A, the system's synchronization dynamics are inextricably linked to the temperature-dependent fᵣₑₛ of the LiNbO₃ resonator 525 coupling the POs 201, where the device's impedance sets the system's preference for an in-phase or anti-phase solution. Changes in Tₐ lead to corresponding alterations in the preferred synchronization between POs due to a shift in fᵣₑₛ and the subsequent interacting dynamics between POs. This feature permits the Ising tags to identify when Tₐ passes a certain temperature threshold (Tₜₕ) by detecting changes in the measured Pₒᵤₜ.

Consequently, it becomes critical to examine the parameters that lead to the expression of one synchronization solution over the other when designing Ising tags for implementing accurate threshold sensing. In particular, and especially given the symmetrical nature of Ising tags' circuits, a symmetry analysis of the system was conducted to describe its operational modes (even and odd modes) and elucidate the dynamical interactions between the POs. To this end, the Ising tag 300 is modeled as two POs 301 each terminated with a load resistance (R_{L}) 350 and coupled together using some arbitrary impedance Z_{C} 325 as shown in FIG. 3A. The “Even and Odd Mode” circuit analysis technique was employed to decompose the Ising tag model into two subcircuits delineating the circuital interactions required to produce in-phase solutions (even mode, FIG. 3b) or anti-phase solutions (odd mode, FIG. 3C). These 5 subcircuits were extracted by cutting the model circuit in FIG. 3A along its axis of symmetry and placing an open circuit (even mode) or ground (odd mode) at any points that were cut along the symmetry line. When following this approach, it is clearly observed that the odd mode decomposition includes Z_{C} 325 in parallel with R_{L} 350 while the even mode subcircuit's output is solely comprised of R_{L} 350. In other words, the odd mode subcircuit explicitly details the flow of current through Z_{C} while the even mode circuit illustrates a lack of current flow through Z_{C}. Consequently, the phase synchronization solution preferred by the system maps to the coupling between POs which sets the exchange of current through Z_{C}. To understand what drives the flow of current through Z_{C}, it is useful to recall that the parametric gains of a system must compensate its total losses in order to initiate subharmonic generation. Furthermore, the subcircuits shown in FIGS. 3B and 3C exhibit differing efficiencies in generating parametric gain and different intrinsic total losses due to the impact of the element Z_{C} 325 in parallel with R_{L} 350 at the subcircuit's output. The inclusion of Z_{C} in the odd mode circuit leads the even and odd mode subcircuits to require different power thresholds, P_{th,E} and P_{th,O}, respectively, to activate the excitation of their subharmonic oscillations as shown in FIG. 3E. In this regard, the subcircuit mode requiring the minimum power to trigger the period doubling regime consequently becomes the dominant configuration to describe the current flowing through Z_{C} in the Ising tag. This preference for minimizing energy occurs naturally in systems of bistable coupled POs due to their collective dynamics that gradually reduce a system-level Hamiltonian through some optimization function. Therefore, the subcircuit first activated when the system's power level is pumped starting from below to above threshold corresponds to the mode and phase synchronization solution yielding the lowest system energy. Furthermore, the phase solution encoded within the magnitude of Pₒᵤₜ after power combining the output signals generated by each PO indicates whether the system's energy is minimized by allowing current to flow through Z_{C}. Thus, an in-phase synchronization is activated when having no current flow through Z_{C} is energetically less expensive than the alternative. The opposite relation holds for the activation of anti-phase synchronization.

To evaluate the behavior of Ising tags for different types of Z_{C}, a study was conducted using an analytical model to extract the Pₜₕ for the even and odd mode circuit decompositions of the Ising tag as shown in FIGS. 3B and 3C. Note that the even mode circuit decomposition of the Ising tag is equivalent to the circuit of a single PFD, meaning that P_{th,E} is identical to Pₜₕ, as explained in greater detail below with reference to Ising tag design, including particular discussion with respect to design of the prototype Ising tag 500 design of FIG. 5A. P_{th,O}, on the other hand, considers the effect of Z_{C} on changing the total load impedance at the output subsequent potential detuning of the resonant conditions facilitating subharmonic generation. Referring now to FIGS. 4A-4C, the difference between P_{th,E} and P_{th,O} was numerically extracted at 438 MHz, the optimal fₒᵤₜ for the PFDs in the Ising tag when considering Z_{C} 325 as 1) a resistor, 2) an inductor, and 3) a capacitor, and when sweeping the value of Z_{C} to encompass a large range of resistance and reactance. As can be seen in FIG. 4A and FIG. 4B, P_{th,O} always yielded a smaller value than P_{th,E}, indicating that the odd mode solution would always be expressed when using a purely resistive or purely inductive Z_{C} 325. This was also confirmed by harmonic balance simulation techniques plotting the time domain evolution of the subharmonic oscillations. On the other hand, as shown in FIG. 4C, sweeping the reactance of a purely capacitive Z_{C} 325 realizes a shift from anti-phase solutions to in-phase solutions with increasing capacitance. Importantly, this result suggests that any PoI-sensitive element with a capacitive readout can be used as the coupling element in an Ising tag implementing threshold sensing. This transition point between the P_{th,E} and P_{th,O} marks the region of Z_{C} values adversely affecting the P_{th,O} and thus driving the system to prefer in-phase synchronization due to its lower energy requirements. Furthermore, in this region, the reduction of parametric losses due to offsetting R_{L} is dominated by the loss in gain efficiency owing to Z_{C} effectively detuning of the resonant conditions governing the PFDs. Generally, it becomes clear that the mapping of some PoI to a capacitive Z_{C} enables changing of which mode is least energetically expensive as a function of the adopted PoI.

In this regard, referring now to FIGS. 4D and 4E, a temperature sensitive LiNbO₃ microacoustic resonator 525 operating in the S₀ mode as Z_{C} was investigated to control the phase synchronization of the Ising tag with respect to Tₐ. The Butterworth Van-Dyke (BVD) model used to express the behavior of the resonator in the electrical domain is used as Z_{C} in the odd mode subcircuit, as shown in FIG. 4D. The fabrication, design, and modelling of the LiNbO₃ resonator 525 is discussed in further detail below. However, in general, such a resonator is comprised of several temperature-dependent reactive and resistive elements producing a temperature-dependent fᵣes. The difference between P_{th,E} and P_{th,O} when embedding a LiNbO₃ resonator 525 in the odd mode subcircuit was analyzed when considering different Tₐ (or different fₑₛ) for an fₒᵤₜ equal to 438 MHz. As seen in FIG. 4E, as Tₐ increases, the preferred mode moves from the even mode to the odd mode due to shifts in the impedance of Z_{C} that change the conditions of current flow in the circuit. Thus, the Ising tag is able to exploit mode competition to manifest the mode engendering the least amount of energy. Additionally, because the synchronization dynamics of two coupled parametric oscillators induced by Z_{C} operate independently of Pᵢₙ, Ising tag circuits can be used to create a threshold sensor having a sensed accuracy immune to multipath limitations.

### Ising Tag Design, Prototyping, and Experimentation

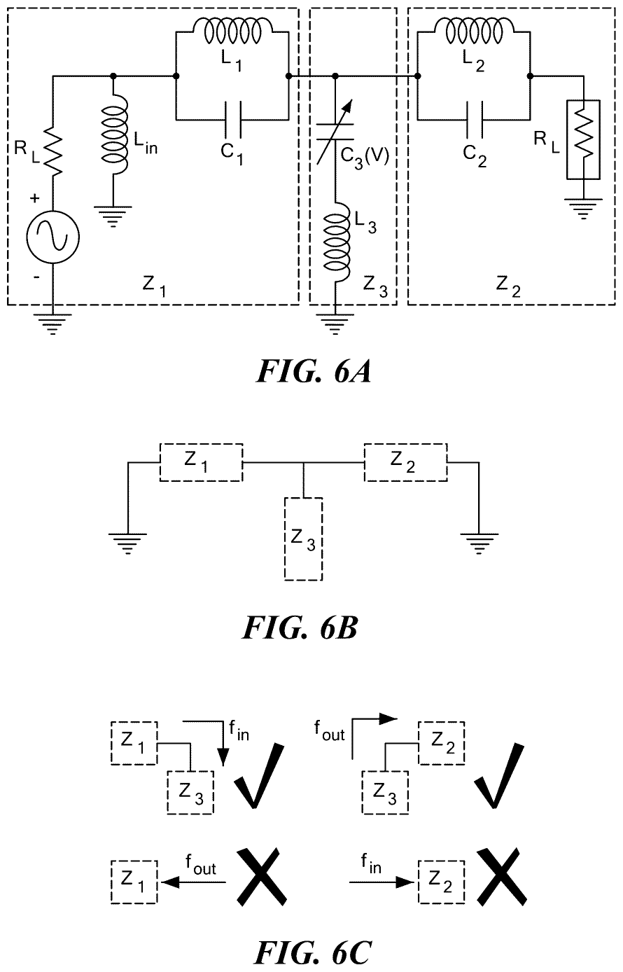

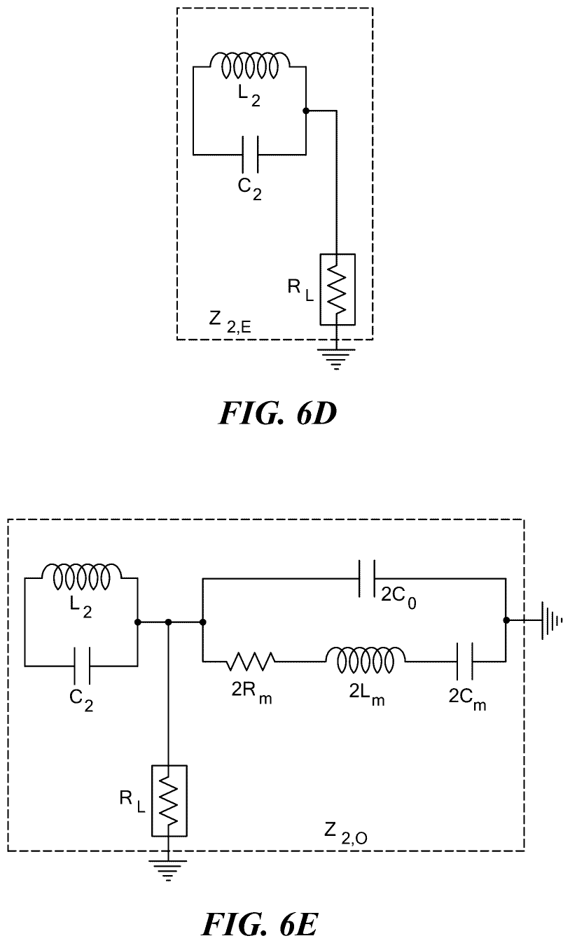

With regard to Ising tag design, the main design goals of the PFDs in Ising tags can advantageously be focused on minimizing the Pₜₕ required to excite subharmonic generation while properly isolating the frequency divided signal to the output meshes of the PFDs (see FIGS. 6A and 6B). To do this, circuital branches (Z₁, Z₂, and Z₃) were designed obeying the four resonant conditions detailed below and shown in FIG. 6C:
1. The mesh including the series of Z₁ and Z₃ should series resonate at fᵢₙ.
2. Z₂ should act as a notch-filter for fᵢₙ.
3. The mesh including the series of Z₂ and Z₃ should series resonate at fₒᵤₜ.
4. Z₁ should act as a notch-filter for fₒᵤₜ.

The satisfaction of these four resonant conditions permits the design a circuit that maximizes voltage modulation at fᵢₙ across the nonlinear element hosted in Z₃ while strongly directing such generated subharmonic signal towards the PFD's output port. Because PFDs obey resonance conditions distributed between a combination of three meshes, they exhibit significantly lower Pₜₕ than other electrical realizations of parametric oscillators due to a larger efficiency in optimizing parametric gains and losses. Using a commercial Harmonic Balance simulator, the power auxiliary generator (pAG) technique was exploited to perform an optimization routine and acquire the component values leading to the minimization of Pₜₕ. This optimization process was conducted in conjunction with electromagnetic (EM) simulations of the printed circuit board (PCB) hosting the PFDs to account for the parasitic reactance arising from the traces of the PCB and SMA connectors. This simulation framework also considered the compatibility of the selected lumped components with the commercially available discrete component values, ensuring that the built PFDs would retain optimal performance when using off-the-shelf lumped components. Furthermore, the PFDs were designed to operate with fᵢₙ roughly equal to 878 MHz, which is about twice the resonant frequency of the LiNbO₃ 525 used to couple the PFDs 501 of the prototype Ising tag 500 shown in FIG. 5A. The selected component values for the prototype Ising tag 500 are listed in Table 1.

TABLE 1
Components list of the experimental prototype Ising tag:

| Component | Nominal Value | |
|---|---|---|
| L₁ | 8.2 | nH |
| L₂ | 47 | nH |
| L₃ | 16 | nH |
| Lᵢₙ | 2 | nH |
| C₁ | 5.2 | pF |
| C₂ | 2.0 | pF |
| C₃ | 1.2 | pF |

As for the calculation of the P_{th,E} and P_{th,O} for the even and odd mode decompositions of the coupled POs embedded in the Ising tag, an analytical expression, based on the satisfaction of the above resonance conditions was used. This analytical treatment considered changes in the Z₂ branch owing to the parallel of R_{L} with Z_{C}∥Z_{C} as the only circuital difference distinguishing P_{th,O} from P_{th,E}. FIGS. 6D and 6E show the Z_{2,E} and Z_{2,O} used for calculating P_{th,E} and P_{th,O}, respectively.

The prototype Ising tag 500 of FIG. 5A was developed to demonstrate the operation of Ising tags. The prototype Ising tag 500 is comprised of two identical POs, 501 coupled together with the LiNbO₃ micro acoustic resonator 525 and later power combined at their outputs.

These POs 501 are each constructed as identical PFDs according to the schematic shown in FIG. 6A, using off-the-shelf components having the properties listed in Table 1. The PFDs 501 are RF implementations of two-port degenerate POs, each containing one input mesh and one output mesh that are each formed using sets of lumped electronic components and an antenna (e.g., input antenna 550 and output antenna 575, respectively). Both meshes share a shunt branch containing a solid state hyperabrupt varactor and an inductor that operates as a nonlinear reactance. The input and output mesh contain a set of notch filters (~438 MHz and ~876 MHz, respectively), constraining the interrogation signal in the input mesh while constraining the parametrically generated subharmonic into the output mesh. Additionally, a lumped component impedance transformation stage is included in the Ising tag's input mesh to reduce the impact of loading on the achieved Pₜₕ.

The LiNbO₃ resonator 525 used to couple the PFDs 501 operates as the PoI-sensitive component determining the Ising tag's dominant phase synchronization solution after its activation. Such a resonator with fᵣₑₛ=438 MHz, Qₛₗₒₚₑ=2213.92, and kₜ²=16.84% was selected due to the closeness of its fᵣₑₛ with the fₒᵤₜ of the PFDs and for its piezoelectric material's strong relationship of fᵣₑₛ with Tₐ due to the innate properties of the LiNbO₃.

Fabrication of LiNbO₃ microacoustic resonator

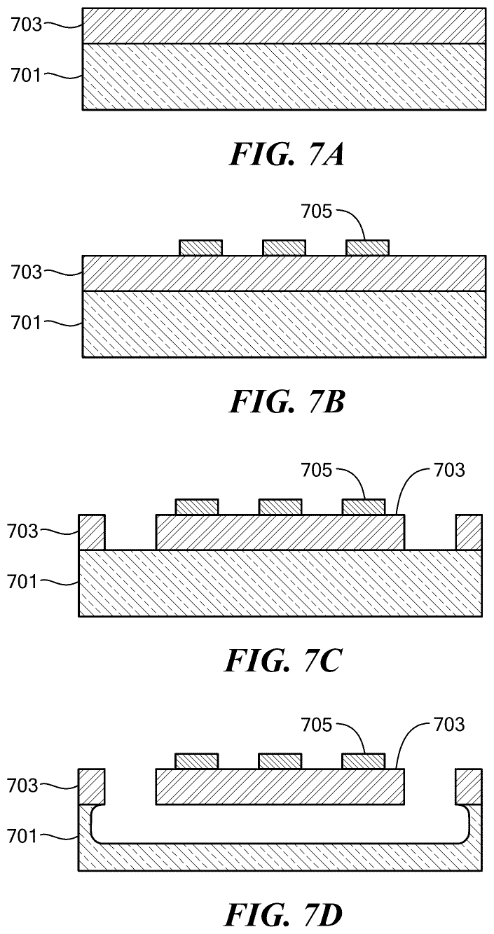

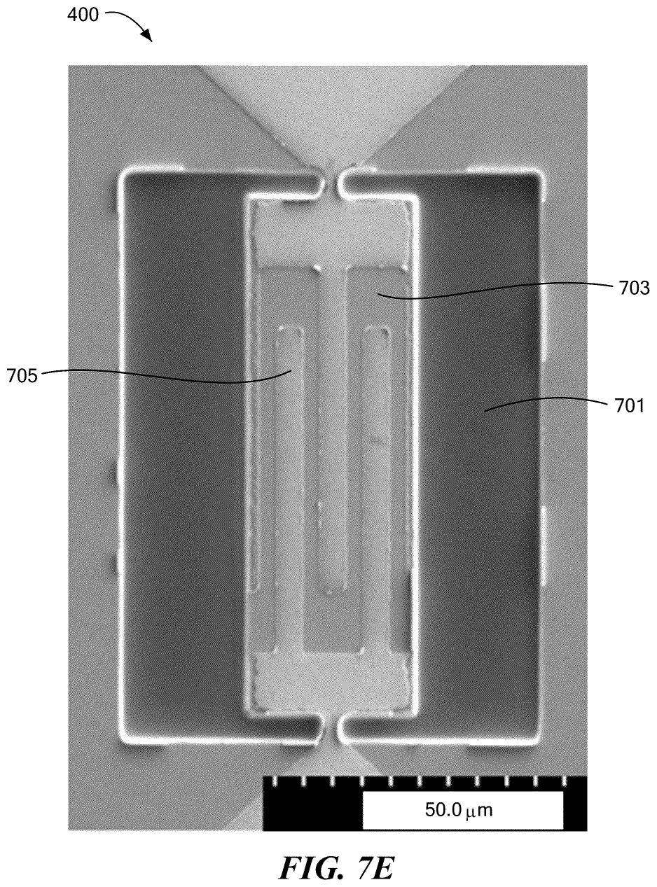

Referring now to FIGS. 7A-7E, the X-Cut LiNbO₃ resonator 525 used in the prototype Ising tag 500 was designed as an S₀ mode Laterally Vibrating Resonator (LVR) operating with a resonance frequency of approximately 438 MHz. Such a resonator was fabricated using the fabrication process illustrated in FIGS. 7A-7D. First, as shown in FIG. 7A, a bulk lithium niobate wafer 703 was bonded onto a high resistivity silicon wafer 701 through surface activation bonding by NGK, Ltd. Then, using trimming and chemical mechanical polishing, the layer of LiNbO₃ was polished to a desired thickness of 1 μm. After this, as shown in FIG. 7B, a 200 nm layer of AlSiCu was sputtered and patterned using chlorine-based reactive ion etching to form the resonator's interdigitated electrodes 705. Then, as shown in FIG. 7C, the resonator plate was patterned using an anisotropic ion beam etch with a 72° substrate angle. Finally, as shown in FIG. 7D, the device was released from the silicon substrate using 18 cycles of XeF₂ isotropic etching. A SEM image of the fabricated resonator is shown in FIG. 7E.

Although described herein as being fabricated according to the specific process set forth in FIGS. 7A-7E, it will be apparent in view of this disclosure that such LiNbO₃ resonators can be manufactured by any suitable process and can make use of any suitable substrate and/or electrode materials, in any configuration or number suitable to achieve desired electrical and resonant properties.

### Temperature Coefficient of Frequency (TCF) for LiNbO₃ Resonator

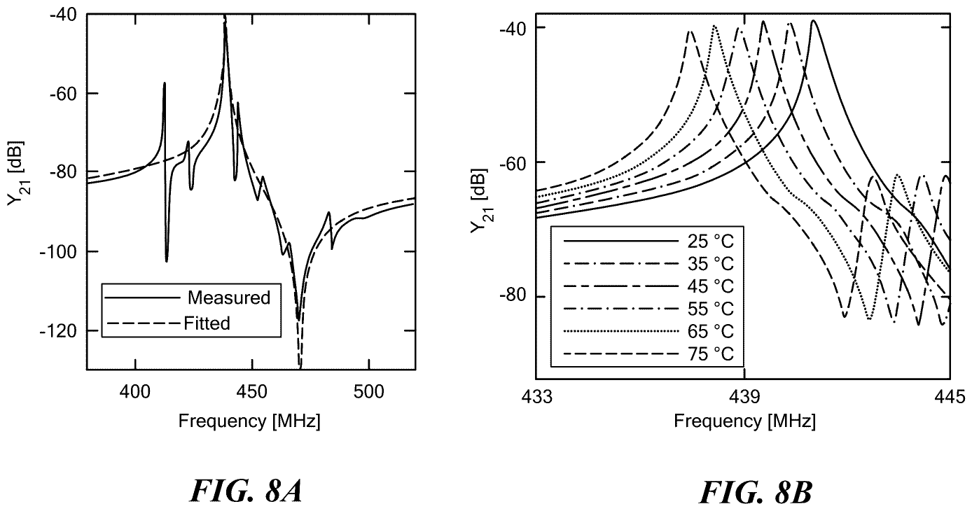

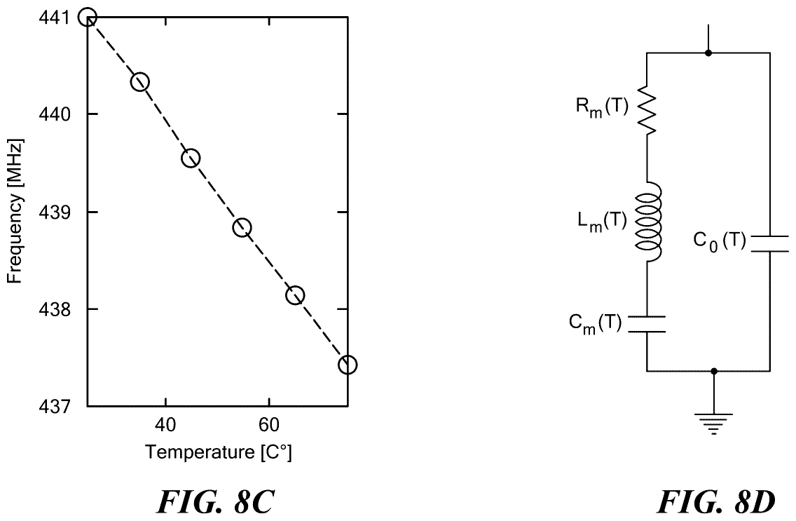

The S-parameters of the fabricated resonator were characterized in laboratory conditions via direct wafer probing. Its admittance was extracted via software, and the device's electrical performance was fitted to the BVD model. When measured, the device exhibited fᵣₑₛ of 438.464 MHz, kₜ² of 1684%, and Qₛₗₒₚₑ of 2213.92. These parameters yielded an equivalent motional resistance (Rₘ), motional inductance (Lₘ), motional capacitance (Cₘ) of 75.69 Ω, 44.55 μH, and 2.96 fF, respectively, when modelled in the electrical domain. The static capacitance (C₀), indicating the intrinsic capacitance of the interdigitated structure at rest, was fitted as 19.47 fF (see FIG. 8A). After these measurements, the device was wire-bonded onto the PCB hosting the Ising tag's components and the admittance was re-extracted from the two output ports of the Ising tag, resulting in a ~3 MHz shift in fᵣₑₛ up to 441.45 MHz due to electrical loading caused by the traces of the PCB and wirebonds. Then, the TCF was extracted for the LiNbO₃ hosted on the Ising tag's PCB with components already soldered within the operational temperature range of the experiments conducted as described herein. This was done by changing Tₐ from room temperature up to 75° C. in steps of 10° C. and measuring the resultant fᵣₑₛ of the device (see FIG. 8B). Subsequently, the device's TCF was extracted by mathematically fitting a value for TCF to a first order expression relating fᵣₑₛ, Tₐ, and TCF with respect to the ambient temperature. This device's TCF was measured as −190 ppm, which is 2.5 times larger than the typical first order TCF values of S₀ mode LVRs hosted on LiNbO₃ when measured in isolation (see FIG. 8C). However, this extracted TCF includes the culminated temperature dependence of all elements loading the resonator including the PCB's substrate, wirebonds, and lumped surface mount components. Consequently, when modelling the Ising tag in the circuital simulations, the extracted TCF was embedded within the BVD model to replicate the measured shifts in fᵣₑₛ as a function of Tₐ (see FIG. 8D).

### Experimental Setups

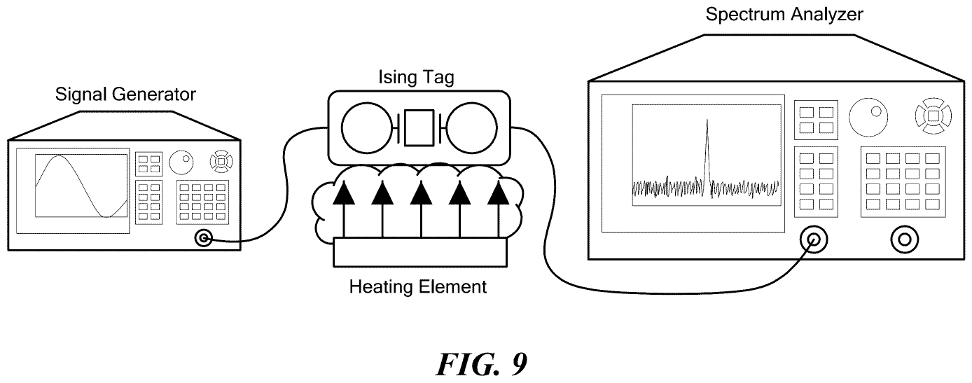

The experimental setup used to characterize the performance of the Ising tag prototype 500 is shown in FIG. 9. The input port of the Ising tag was fed with a continuous-wave (CW) signal generated from a signal generator transmitting a signal at 878.0 MHz while the output of the Ising tag was connected to a spectrum analyzer to monitor the output power of the device. The input power transferred to the Ising tag 500 was manually swept when considering different fᵢₙ to determine the device's Pₜₕ across a range of frequencies and to extract the relationship between Tₜₕ and fᵢₙ. Other wired experiments replaced the spectrum analyzer at the output of the power combined PFDs in the Ising tag with an oscilloscope to which the output of each PFD was directly connected in separate ports. Additionally, the phase synchronization was measured either through the output power of the Ising tag in the frequency domain using a spectrum analyzer to extract the relationship between Tₜₕ, fᵢₙ, and Pᵢₙ or in the time domain using an oscilloscope to measure the effect of Pᵢₙ on Δφ. When extracting the time domain measurements of the coupled POs 501, the power combining element was removed to isolate the waveforms generated from each PO 501 into separate ports in the oscilloscope.

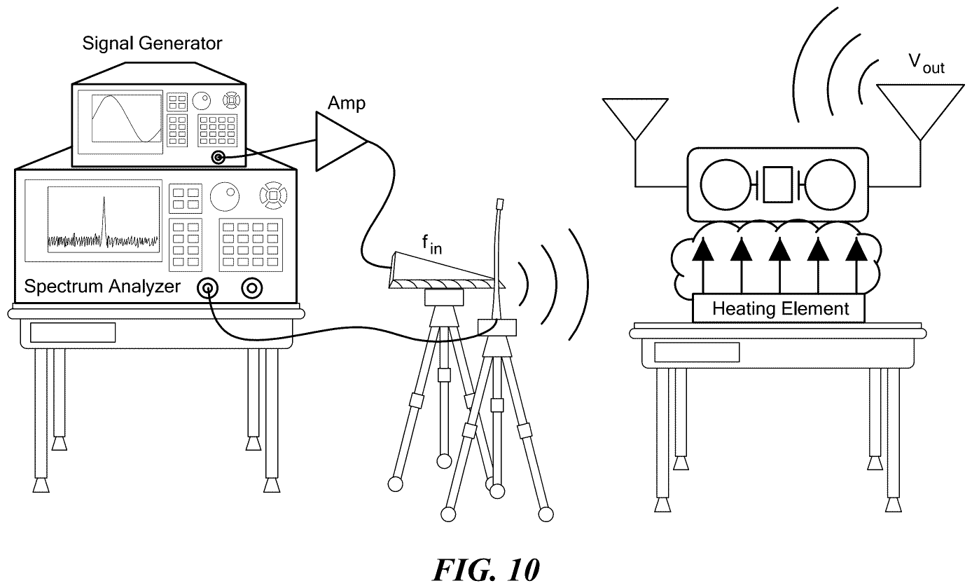

The prototype Ising tag 500 was also wirelessly characterized by performing a wireless testing as shown in FIG. 10. That experiment emulated a transceiver representing an interrogator sending an interrogating signal to excite the Ising tag and reading out the Ising tag's response when considering different fᵢₙ and Tₐ. To accomplish this, the CW interrogating signal with an effective isotropic radiated power (EIRP) of up to +30 dBm was transmitted through a wideband log-periodic antenna after amplifying it with a power amplifier. Additionally, the Ising tag's backscattered signal was received through an isotropic dipole antenna connected to a spectrum analyzer to characterize the Pₒᵤₜ.

The Ising tag was terminated at its input and output ports with two isotropic dipole antennas operating near fᵢₙ and fₒᵤₜ, respectively. The Ising tag was then placed onto a heating element positioned 1 m away from interrogating/reading antennas, while ensuring that all antennas were at the same height, as shown in FIG. S5. For different fᵢₙ and Tₐ, the EIRP was swept from +20 dBm (representing a Pᵢₙ incident to the Ising tag which is lower than Pₜₕ) up to +30 dBm, corresponding to an incident Pᵢₙ approximately equal to 0 dBm.

### Experimental Results

To characterize the response of the Ising tag, the Pₜₕ of each of the coupled PFDs was measured by performing a wired experiment (shown in FIG. 9) in which the input and output ports of a single PFD hosted on the Ising tag were directly connected to a signal generator and a spectrum analyzer, respectively. The signal generator was configured to produce a signal with a frequency equal to fᵢₙ at a very low power. Then, the applied RF power was gradually swept upwards until a bifurcation was noted at fₒᵤₜ on the spectrum analyzer, marking Pₜₕ (−7.2 dBm). The Pₜₕ was characterized and averaged for both PFDs on the Ising tag over a range of frequencies near fᵢₙ, as shown in FIG. 5A, to validate the RF performance of the PFD across the range of interrogation frequencies of the Ising tag. This Pₜₕ value also denotes the maximum operational range of such an Ising tag when interrogated wirelessly. Then, a similar procedure was conducted to characterize Pₒᵤₜ of the Ising tag with respect to Tₐ when the coupled PFDs are power combined at their outputs to validate whether the Ising tag could signal a violation in some Tₜₕ through a change in Pₒᵤₜ (see FIG. 5B). To this end, a 50Ω matched antenna was placed at both the input and output ports of the Ising tag and the Ising tag was positioned on top of a heating element 1 m away from the interrogator. The heating element was configured to produce a value of Tₐ onto the LiNbO₃ resonator equal to 25° C. Then, the Ising tag was wirelessly interrogated at different frequencies in the range of 852 MHz to 888 MHz, with steps of 1 MHz. For each frequency value, the power incident onto the Ising tag was gradually swept from a value much lower than Pₜₕ up to 0 dBm, which is above Pₜₕ, in steps of 0.5 dBm. When conducting this experiment, two easily differentiable outcomes for Pₒᵤₜ were observed throughout the range of measured frequencies, reflective of the even and odd mode solutions yielding in-phase and anti-phase synchronization solutions, as discussed in the previous section. It should be noted that there were two frequency points, 866 MHz and 881 MHz, that function as boundary points dividing the region of even solutions from those of odd solutions. In particular, at 25° C., the Ising tag always expressed in-phase synchronization between 866 MHz and 881 MHz, as evidenced by the correspondingly large Pₒᵤₜ. This indicates that P_{th,E} was lower than P_{th,O} and that the even mode subcircuit dominated over the odd mode in this range of frequencies. Outside of this range, the value of Pₒᵤₜ was low, indicating a dominance of the odd mode or anti-phase synchronization solution. This procedure was repeated for Tₐ ranging from 25° C. to 75° C. in steps of 5° C., using an infrared temperature sensor to ensure that Tₐ reached its expected steady state temperature value. While increasing Tₐ, the boundary frequency points dividing the regions of different dominant modes shifted downwards monotonically, in line with expectations when considering the negative temperature coefficient of frequency (TCF) of LiNbO₃ substrates (see FIG. 5B). For all values of Tₐ characterized in this study, two odd mode regions always bounded a single even mode region. In this regard, the lower frequency boundary zone between the even and odd mode regions provides an effective basis to use the Ising tag as a parametric alarm that generates a strong Pₒᵤₜ as Tₐ exceeds a certain value when keeping a fixed fᵢₙ. Even more, the strategic selection of fᵢₙ permits to tune the value of Tₜₕ by consequently changing the Tₐ required to sufficiently shift the fᵣₑₛ of the LiNbO₃ device and enter the region preferring in-phase solutions. Such features permit a single Ising tag to remotely alert when Tₐ exceeds Tₜₕ for multiple values of Tₜₕ near-simultaneously by simply changing fᵢₙ, which is a particularly useful feature when monitoring cold-chain transportation environments with specific items requiring different Tₜₕ conditions. Even more, because there are two such transitions between odd and even mode regions throughout the frequency range, the built Ising tags' alarm signal can be realized for hot chain in addition to cold chain environments; in other words, the built Ising tag can trigger an alarm when Tₐ exceeds or falls below Tₜₕ, depending on the selected fᵢₙ. Thus, not only can the intelligent selection of fᵢₙ tune Tₜₕ remotely and parametrically, but it can also change the direction in which Tₐ must cross Tₜₕ to trigger the in-phase solution region and manifest a strong Pₒᵤₜ alarm signal. Additionally, because the system relies on the fully reversible shifting of the fᵣₑₛ of a LiNbO₃ device to change the system's coupling dynamics, the demonstrated Ising tag implements a completely non-destructive and reversible approach to passive threshold sensing.

To evaluate the phase synchronization dynamics of the Ising tag against perturbations in its received power, a fully wired experiment was conducted. In this experiment, the Ising tag was positioned onto the same heating element and the output port of each PO's was connected directly to the different ports of an oscilloscope. The Ising tag was then applied an increasing value of Pᵢₙ from below Pₜₕ to −5 dBm and then gradually swept to +5 dBm when Tₐ=50° C. The difference between the phases (Δφ) of the time domain signals of the two POs was computed and this was done for two different frequencies, fᵢₙ=432.3 MHz and fᵢₙ=431.3 MHz, corresponding to Tₜₕ values of 40° C. and 60° C., respectively. These frequencies were selected because they yield opposite phase solutions at Tₐ=50° C. For both solution types, A #remained constant despite increasing levels of Pᵢₙ as shown in FIG. 5C. To further characterize the synchronization dynamics against applied power, another experiment was conducted at which, for several fixed fᵢₙ, Tₐ was gradually increased in steps of 1° C. and Pᵢₙ was swept for each value of Tₐ from a value far below Pₜₕ to the various power levels shown in FIG. 5D. This experiment was performed for 4 different fixed frequencies, fᵢₙ=432.7 MHz, 432.3 MHz, 431.8 MHz, and 431.3 MHz, corresponding to Tₜₕ=30° C., 40° C., 50° C., and 60° C. As shown in FIG. 5D, Pᵢₙ does not affect Tₜₕ, affirming that the synchronization dynamics of the coupled POs is determined by the combination of fᵢₙ and Tₐ rather than Pᵢₙ, which is a major departure from previous nonlinear tag designs relying on exploiting bifurcations dynamics occurring near power-sensitive points of marginal stability. The insensitivity of Ising tags to perturbations in Pᵢₙ provides them with a threshold sensing accuracy resilient to both channel fading and multipath as the sensed Tₜₕ is fully controlled by the interrogator.

Subsequently, to achieve a more precise determination of the frequency transition points throughout the system and gain insight on the tuning of Tₜₕ with respect to fᵢₙ, a fully wired experiment was performed in which some Tₐ was applied and activated the Ising tag was activated with Pᵢₙ swept from below Ph up to 0 dBm, similar to the first experiment but in a wired fashion. This was performed for frequencies between 860 MHz and 882 MHz in steps of 0.1 MHz and for Tₐ ranging from 25° C. to 75° C. in steps of 5° C. Then, for each Tₐ, the frequency points that marked the boundaries of the window of solutions preferring an even mode phase state were recorded and plotted in FIGS. 5E and 5F. These extracted transitional frequency points illustrate the relationship between the selected value of fᵢₙ and its corresponding Tₜₕ. Thus, the prototype Ising tag 500 can operate as a threshold sensor for both the cases when Tₐ exceeds Tₜₕ and when Tₐ falls below Tₜₕ based on the adopted fᵢₙ. A value of fₙ selected near the lower boundary permits to use the Ising tag as a threshold sensor in cold chain applications, where violations are flagged when Tₐ exceeds Tₜₕ; however, the selection of fᵢₙ near the upper boundary permits to use the Ising tag to passively generate an alarm signal when Tₐ falls below Tₜₕ. The measured relation between fᵢₙ and Tₜₕ fits very well with numerically extracted trends using a circuit simulator.

Referring now to FIG. 5G, the operation of the Ising tag device was also validated by placing it on a remote-controlled heated surface and by remotely interrogating it at 904 MHz for different set Tₐ-values ranging from 25° C. to 55° C. The temperature of the resonator was simultaneously measured by using an IR temperature sensor to ensure that each data-point was extracted after reaching the preset steady-state temperature value. At each Tₐ-step, the Ising tag was interrogated by different signals with incident power-values between −1 dBm and +5 dBm and the Ising tag was deactivated following each interrogation. This procedure was repeated three times to validate consistency in performance. The output of the Ising tag was measured wirelessly using an emulated IoT-reader comprised of a spectrum analyzer placed almost on top of the interrogating antenna, as shown in FIG. 3. As the Ising tag's temperature increased above 40° C., a sharp increase was observed in the magnitude of νₒᵤₜ due to a temperature-driven transition to a ferromagnetic interaction between the two POs. Nevertheless, νₒᵤₜ returned to exhibit a negligible magnitude once the temperature of the LiNbO₃ device was set back to below Tₜₕ, as shown in FIG. 5G. As noted above, the demonstrated power-independent synchronization dynamics of the Ising tag make its accuracy resilient to multipath and channel-fading.

### Advantages and Practical Applications

Ising Tags are described herein having coupled RF POs. Such Ising tags are useful in connection with a variety of applications, including, for example, parametrically reconfigurable and passive threshold sensing. Theoretical analysis and experimental validation of such devices reveals a distinct property: the energetic competition between the even and odd modes, and, consequently, the Pₒᵤₜ of Ising tags is independent to changes in the received power above the Ising tags' threshold. This distinctive property advantageously provides passive threshold sensing with an accuracy that is not degraded by multi-path or perturbations in the electromagnetic environment. In fact, by leveraging the collective dynamics of the coupled POs to encode the sensed parameter instead of active components or irreversible changes in a PT's radiation profile, Ising tags enable parametric reconfigurability while avoiding using batteries or energy harvesting circuits. In this regard, these experiments indicate that it is possible to measure violations of various temperature thresholds (or other PoI thresholds) using a singular Ising tag in an uncontrolled electromagnetic environment. The collective dynamics of the coupled POs in Ising tags also permits real-time simultaneous sensing of multiple parameters and sensing-based passive computation for applications demanding sensitive reconfigurable threshold monitoring and accurate read-out capabilities without using battery-powered devices.

While example embodiments have been particularly shown and described, it will be understood by those skilled in the art that various changes in form and details may be made therein without departing from the scope of the embodiments encompassed or contemplated herein.

As used herein, “consisting essentially of” allows the inclusion of materials or steps that do not materially affect the basic and novel characteristics of the claim. Any recitation herein of the term “comprising”, particularly in a description of components of a composition or in a description of elements of a device, can be exchanged with “consisting essentially of” or “consisting of”.

What is claimed is:

1. An Ising tag for threshold sensing of a parameter of interest comprising:
a first parametric oscillator (PO);
a second PO coupled to and power-combined with the first PO; and
a sensor element for sensing a parameter of interest, the sensor element coupling the first and second POs.

2. The Ising tag of claim 1, wherein each PO comprises:
a resonant input mesh driven by a pump signal;
a resonant output mesh coupled to the input mesh through a nonlinear component to form a parametric frequency divider; and
the nonlinear component configured to passively activate, responsive to the pump signal exceeding a threshold power of the PO, a parametric oscillation between the input and output meshes having an oscillation frequency equal to half an angular input frequency of the pump signal,
wherein an output signal of PO can be switched between an in-phase state and an out-of-phase state.

3. The Ising tag of claim 2, wherein the sensor element is configured to set the threshold power of the first and second POs to be exceeded by a power of the pump signal responsive to a value of the parameter of interest exceeding a parameter of interest threshold.

4. The Ising tag of claim 1, wherein the sensor element includes one or more resistive elements, inductive elements, capacitive elements, resonant elements, or combinations thereof.

5. The Ising tag of claim 4, wherein the sensor element produces a capacitive readout.

6. The Ising tag of claim 4, wherein the sensor element includes capacitive elements only.

7. The Ising tag of claim 4, wherein the sensor element is one or more of an environmental sensor, a chemical sensor, a biological sensor, an electrical sensor, mechanical sensor, or combinations thereof.

8. The Ising tag of claim 7, wherein the sensor element is a temperature sensor.

9. The Ising tag of claim 8, wherein the sensor element is a piezoelectric resonator.

10. The Ising tag of claim 9, wherein the sensor element is a lithium niobate (LiNbO₃) resonator.

11. The Ising tag of claim 2, wherein a characteristic of the nonlinear component is modulated at the angular input frequency of the pump signal.

12. The Ising tag of claim 2, wherein the nonlinear component has a nonlinear reactance.

13. The Ising tag of claim 12, wherein the nonlinear component includes one or more of a diode, a varactor, or a combination thereof.

14. The Ising tag of claim 13, wherein the nonlinear component includes a varactor and an inductor, wherein the input mesh and the output mesh are coupled through the varactor and the inductor.

15. The Ising tag of claim 2, wherein:
the input mesh includes an input filter to constrain the pump signal within the input mesh to the angular input frequency of the pump signal; and
the output mesh includes an output filter to constrain the output signal within the output mesh to half of the angular input frequency of the pump signal.

16. The Ising tag of claim 2, wherein the output mesh is configured to series-resonate at half the angular input frequency of the pump signal.

17. The Ising tag of claim 2, wherein each of the input mesh and the output mesh includes a resonator.

18. The Ising tag of claim 17, wherein each resonator includes one or more of an electrical resonator, a MEMS resonator, a NEMS resonator, an optical resonator, a non-Hermitian resonator, an electromagnetic resonator, or a combination thereof.

19. A multiple parameter of interest threshold sensing system comprising:
a first Ising tag including:
a first parametric oscillator (PO);
a second PO coupled to and power-combined with the first PO; and
a first sensor element for sensing a first parameter of interest, the first sensor element coupling the first and second POs; and
a second Ising tag including:
a third parametric oscillator (PO);
a fourth PO coupled to and power-combined with the first PO; and
a second sensor element for sensing a second parameter of interest, the second sensor element coupling the third and fourth POs,
wherein the first sensor element is configured to set a threshold power of the first and second POs to be exceeded by a power of a pump signal responsive to a value of the first parameter of interest exceeding a first parameter of interest threshold, and
wherein the second sensor element is configured to set a threshold power of the third and fourth POs to be exceeded by a power of the pump signal responsive to a value of the second parameter of interest exceeding a second parameter of interest threshold.

20. The multiple parameter of interest threshold sensing system of claim 19, wherein the first and second sensor elements each include one or more of an environmental sensor, a chemical sensor, a biological sensor, a biomedical sensor, an electrical sensor, a mechanical sensor, or combinations thereof.

21. A system for threshold sensing of a parameter of interest comprising:
an Ising tag including:
a first parametric oscillator (PO);
a second PO coupled to and power-combined with the first PO; and
a sensor element for sensing a parameter of interest, the sensor element coupling the first and second POs;
wherein each PO comprises:
a resonant input mesh driven by a pump signal;
a resonant output mesh coupled to the input mesh through a nonlinear component to form a parametric frequency divider; and
the nonlinear component configured to passively activate, responsive to the pump signal exceeding a threshold power of the PO, a parametric oscillation between the input and output meshes having an oscillation frequency equal to half an angular input frequency of the pump signal,
wherein an output signal of the PO can be switched between an in-phase state and an out-of-phase state,
wherein the sensor element is configured to set the threshold power of the first and second POs to be exceeded by a power of the pump signal responsive to a value of the parameter of interest exceeding a parameter of interest threshold,
wherein an output signal of the Ising tag can be switched between an in-phase state and an out-of-phase state according to a combined state of the output signals of the first and second POs; and
a reader configured to produce the pump signal and to read the output signal, wherein the reader is configured to detect the in-phase or out-of-phase state of the Ising tag.
